(19) United States
(12) Patent Application Publication
(10) Pub. No.: US 2019/0019703 A1
(43) Pub. Date: Jan. 17, 2019

(54) FLEXIBLE SUBSTRATE SHIPPER

(71) Applicants: Michael L. JOHNSON, North, Chaska, MN (US); Barry M. GALLAGHER, North, Chaska, MN (US); GREGERSON Barry, Deephaven, MN (US); ENTEGRIS, Inc., Billerica, MA (US)

(72) Inventors: Gary M. Gallagher, Austin, TX (US); Barry Gregerson, Excelsior, MN (US); Michael L. Johnson, Minneapolis, MN (US)

(21) Appl. No.: 16/076,817

(22) PCT Filed: Feb. 9, 2017
(86) PCT No.: PCT/US17/17234

§ 371 Date: Aug. 9, 2018

Related U.S. Application Data
(60) Provisional application No. 62/303,648, filed on Mar. 4, 2016.
(60) Provisional application No. 62/294,111, filed on Feb. 11, 2016.
(60) Provisional application No. 62/293,240, filed on Feb. 9, 2016.

(51) Int. Cl. H01L 21/673

(52) U.S. Cl. CPC H01L 21/67386; H01L 21/67346; H01L 21/67379; H01L 21/67373; H01L 21/67369

(57) ABSTRACT

A substrate container (100) includes a receptacle (105) and a cover (110). The receptacle (105) includes a base portion (115) for supporting a substrate and a side wall portion (120) extending upward from the base portion (115). The cover (110) defines a closure over the receptacle (105). In one embodiment, the receptacle (105) includes a first alignment feature (300, 305) located on an exterior surface of the receptacle (105). The first alignment feature (300, 305) interfaces with automation for aligning the receptacle (105). In another embodiment, the cover (110) includes a contoured surface (135) for applying a compressive load to the contents of the substrate container (100).

### CROSS REFERENCE TO RELATED APPLICATIONS

This application claims the benefit of U.S. Provisional Application No. 62/293,240, which was filed on Feb. 9, 2016, U.S. Provisional Application No. 62/294,111, which was filed on Feb. 11, 2016, and U.S. Provisional Application No. 62/302,648 which was filed on Mar. 4, 2016. The entire content of the applications are incorporated herein by reference.

### TECHNICAL FIELD

The disclosure relates generally to containers for storing and transporting substrates.

### BACKGROUND

When storing and transporting substrates, it is important that the containers used are designed to prevent the substrates from being damaged. Preferably, the containers are also compact and designed to facilitate deposition of substrates therein and removal of substrates therefrom. In addition, it is beneficial for a given container to be able to safely transport different numbers and types of substrates. In view of the above, there is a need in the art for containers that meet these various criteria.

### SUMMARY

The present disclosure relates generally to substrate containers for storing and transporting flexible substrates. For purposes of this disclosure, the term “flexible” indicates that the substrate when supported by its periphery or individual points is unable to maintain a substantially planar condition without applied tension. In one illustrative embodiment, a substrate container comprises a receptacle and a cover. The receptacle includes a base portion configured to support a flexible substrate and a side wall portion extending upward from the base portion. The cover is configured to define a closure over the receptacle. In one variation, the receptacle includes a first alignment feature located on an exterior surface of the receptacle. The first alignment feature is configured to interface with automation for aligning the receptacle. In another variation, the cover includes a contoured surface configured to apply a compressive load to the contents of the substrate container. Flexible substrates, when aligned and stored properly are capable of withstanding a level of compressive forces without experiencing damage to the substrate. The compressive forces hold the substrate or substrates in place during storage and transport. The contoured surface extends downward relative to a remainder of the cover. In one illustrative embodiment, the contoured surface is in the shape of a cross.

Preferably, the receptacle further includes a second alignment feature located on the exterior surface of the receptacle. The second alignment feature is configured to interface with automation for aligning the receptacle. In one illustrative embodiment, the first alignment feature is a recessed oval or rectangular boss, and the second alignment feature is a recessed circular boss. The circular boss lies along a major axis of the oval boss.

The side wall portion can include planar sections and corners that bridge adjacent ones of the planar sections, the corners protruding outward to define relief areas. The cover can include a stacking feature configured to retain a second substrate container stacked atop the substrate container.

In one illustrative embodiment, a spacer is mounted in the receptacle, the spacer being configured to elevate a substrate relative to the base portion. The spacer includes an RFID device programmed to convey information about the substrate.

In one illustrative embodiment, a protective insert includes a polymer core clad on a first side by a first protective layer and clad on a second side by a second protective layer possibly but not inclusive to a foam or Tyvek type material. The protective insert is configured to prevent collisions between substrates within the substrate container. An exposed edge portion of the polymer core extends laterally from the first and second protective layer. Preferably, an aperture is defined in the exposed edge portion.

The preceding summary is provided to facilitate an understanding of some of the innovative features unique to the present disclosure and is not intended to be a full description. A full appreciation of the disclosure can be gained by taking the entire specification, claims, drawings, and abstract as a whole.

### BRIEF DESCRIPTION OF THE DRAWINGS

The disclosure may be more completely understood in consideration of the following description of various illustrative embodiments in connection with the accompanying drawings, in which:

FIG. 1 is a perspective view of a substrate container in accordance with an embodiment of the present invention.

FIG. 2 is a perspective view of a receptacle of the substrate container.

FIG. 3 is a perspective view of the bottom of the receptacle.

FIGS. 4A, 4B, and 4C show the substrate container.

FIGS. 5A and 5B show the top and bottom of a spacer in accordance with an embodiment of the present invention.

FIG. 6 is a perspective view of an open substrate container in accordance with an embodiment of the present invention.

FIG. 7 is a perspective view of the substrate container of FIG. 6 in a closed configuration.

FIG. 8 is a perspective view of a latch member of the substrate container of FIG. 6.

FIG. 9 is a partial sectional view of the substrate container of FIG. 6 with a latch in an unlatched configuration.

FIG. 10 is a partial sectional view of the substrate container of FIG. 6 with the latch in a latched configuration.

FIGS. 11A and 11B show a protective insert in accordance with an embodiment of the present invention.

FIG. 12 is a partial cutaway view of the substrate container of FIG. 11 with the protective insert of FIGS. 11A and 11B disposed interstitially between substrates.

While the disclosure is amenable to various modifications and alternative forms, specifics thereof have been shown by way of example in the drawings and will be described in detail. It should be understood, however, that the intention is not to limit aspects of the disclosure to the particular illustrative embodiments described. On the contrary, the intention is to cover all modifications, equivalents, and alternatives falling within the spirit and scope of the disclosure.

### DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The following detailed description should be read with reference to the drawings in which similar elements in different drawings are numbered the same. The detailed description and the drawings, which are not necessarily to scale, depict illustrative embodiments and are not intended to limit the scope of the disclosure. The illustrative embodiments depicted are intended only as exemplary. Selected features of any illustrative embodiment may be incorporated into an additional embodiment unless clearly stated to the contrary.

The storage and transport of flexible substrates often demands that the substrates remain substantially flat in order to prevent damage to the substrate. Additionally, it is preferable that the substrates do not shift or move while being transported. Certain embodiments of this disclosure provide a substrate shipper that enables the storage and transport of flexible substrates substantially while reducing the potential for damage to the substrates.

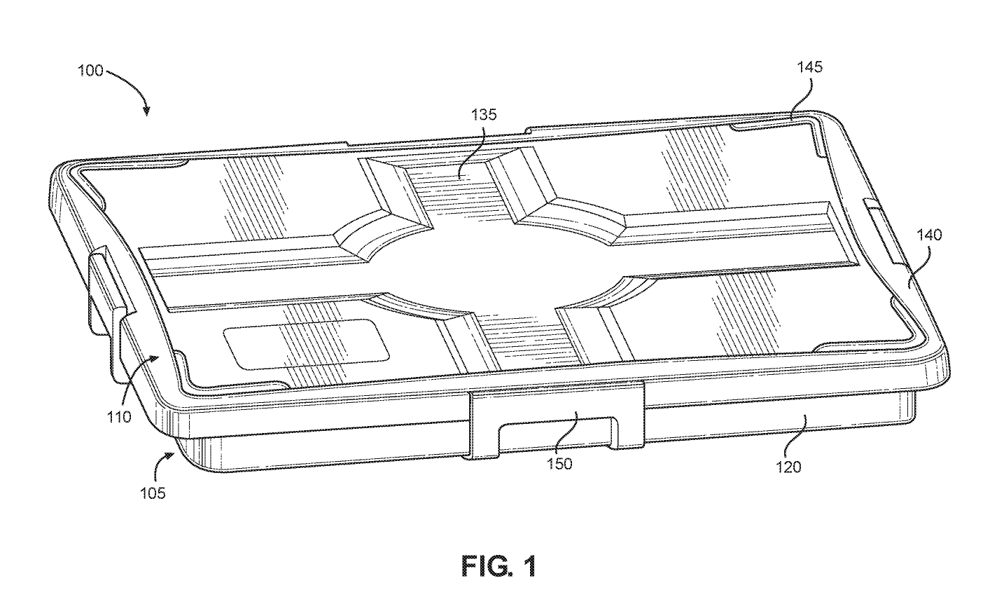

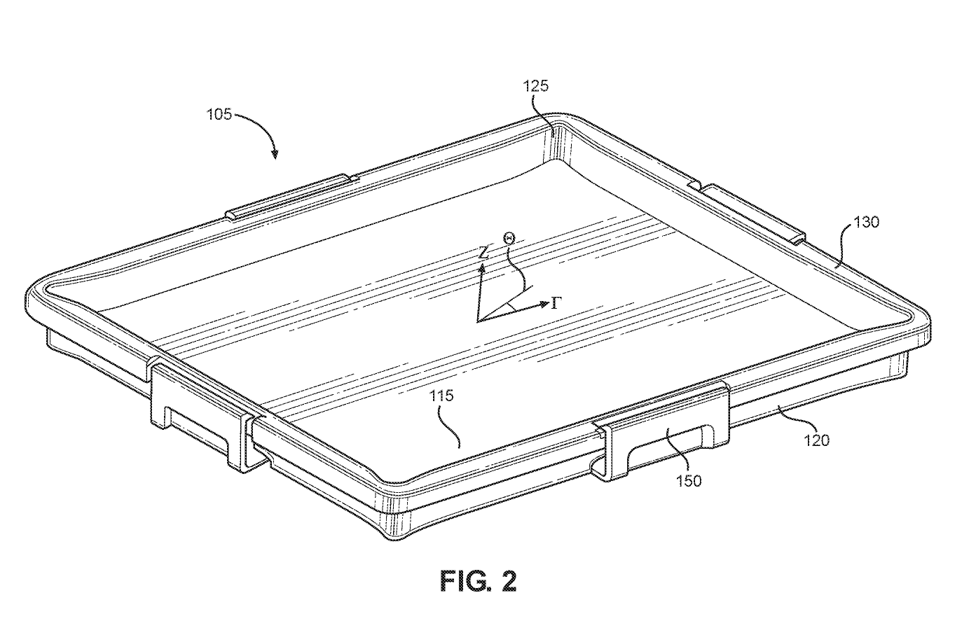

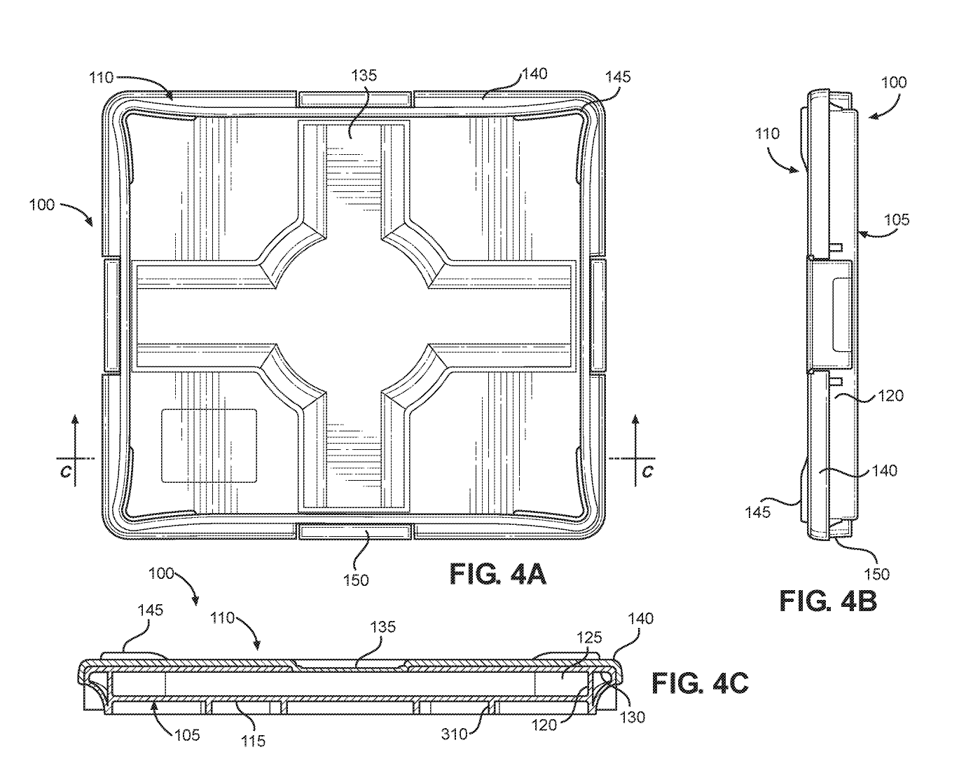

Referring to FIGS. 1-3, 4A, 4B, and 4C, a substrate container or shipper 100 is depicted in accordance with an embodiment of the present invention. Substrate container 100 includes a receptacle 105 and a cover 110. Receptacle 105 includes a rectangular base portion 115 defining a planar interior surface, with a continuous side wall portion 120 extending from base portion 115. Side wall portion 120 includes planar sections that are perpendicular to the planar interior surface of base portion 115. Side wall portion 120 includes corners (one of which is labeled 125) that bridge adjacent ones of the planar sections, the corners protruding outward to define relief areas. Receptacle 105 includes a rim portion 130 extending radially outward from side wall portion 120. Cover 110 includes a contoured surface 135 for applying a compressive load to the contents of substrate container 100 when cover 110 is coupled to receptacle 105.

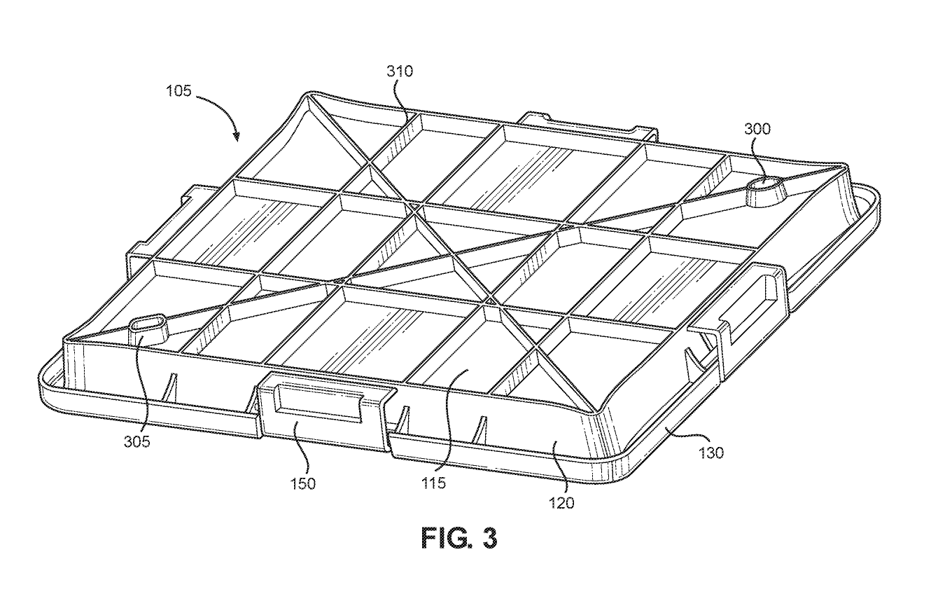

As best seen in FIG. 3, base portion 115 of receptacle 105 includes an exterior surface opposite the interior surface with alignment features (e.g., circular, slot socket kinematic couplings, or combinations thereof), disposed thereon for alignment to automation. In particular, the alignment features include a recessed circular boss structure 300 and a recessed oval or rectangular boss structure 305, boss structures 300 and 305 extending axially from the exterior surface. In the depicted embodiment, oval boss structure 305 defines a major axis that is in substantial alignment with circular boss structure 300. The exterior surface can also be reinforced with ribbing 310 to create structure for maintaining the flatness of the interior surface.

Cover 110 is configured to define a closure over receptacle 105. In the depicted embodiment, cover 110 includes a rim portion 140 configured to surround rim portion 130 of receptacle 105. Cover 110 can include features 145, proximate a perimeter thereof, configured to retain a second substrate container stacked atop cover 110.

A plurality of latches (one of which is labeled 150) is configured to secure cover 110 to receptacle 105. Each of the latches is pivotally mounted to one of receptacle 105 and cover 110. In the depicted embodiment, the latches are mounted to receptacle 105.

In some embodiments, a radio frequency identification (RFID) device is integrated into substrate container 100. Also, receptacle 105 and cover 110 can be fabricated from polymers that are electrostatic dissipative (ESD).

Functionally, the perpendicularity between the planar interior surface of receptacle 105 and the planar sections of side wall portion 120 provides alignment for a stack of flexible substrates disposed in substrate container 100. One such stack can be seen in FIG. 17. In some embodiments, the latches are over-center toggle type latches that create a high clamping pressure for ease of assembly. Contoured surface 135 of cover 110 can be configured to apply a compressive load to the resident substrates directly from the latching points. The protruding rim portions enable access from receptacle 105 of substrate container 100 for lifting and safe operator handling. The relief areas in the corners (e.g., corner 125) help prevent corner damage to rectangular substrates in transport and can provide a location for air separation of the resident substrates when being removed. Substrate container 100 can accommodate multiple product thicknesses with foam inserts.

In certain embodiment, the alignment features provide two-point alignment for interfacing with automation. For embodiments incorporating the recessed circular and oval boss geometries, circular boss 300 provides positive location registration of a first alignment point, while recessed oval or rectangular boss 305 enables compensation for uncertainties in the location of a second alignment point. Such uncertainties can be attributed, for example, to fabrication uncertainties and/or varying distances between the automation registration points.

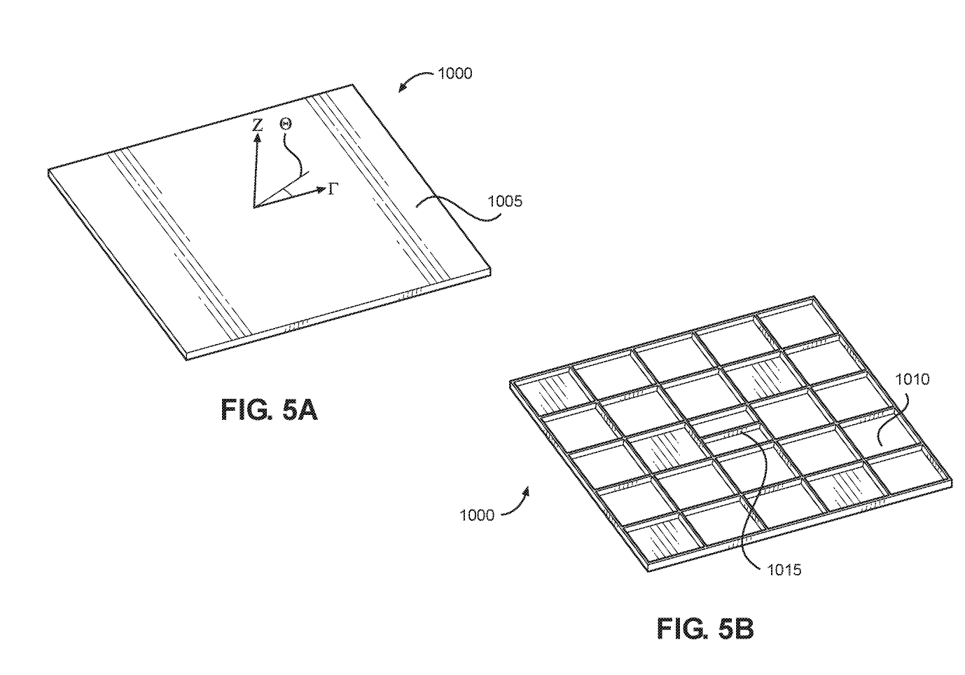

Referring to FIGS. 5A and 5B, a spacer 1000 is depicted in accordance with an embodiment of the present invention. Spacer 1000 is mounted in receptacle 105, and substrates are mounted atop spacer 1000. Spacer 1000 is of predetermined height or thickness dimension (i.e., the dimension in the z-direction) based on the type of substrate that is shipped in substrate container 100. In the depicted embodiment, a top surface 1005 of spacer 1000 is planar and a bottom surface 1010 defines a cored structure. In some embodiments, spacer 1000 includes structure for retaining an RFID device 1015.

Functionally, spacer 1000 elevates a resident substrate stack (not shown) so that cover 110 engages the stack with a desired compressive force. Top surface 1005 provides uniform support to the substrate stack. The cored structure of bottom surface 1010 provides the necessary structural stiffness while reducing material and weight of spacer 1000. Because spacer 1000 is unique to the thickness of the substrates to be stored in substrate container 100, RFID device 1015 can be programmed to convey information about the substrates being stored, including their thicknesses.

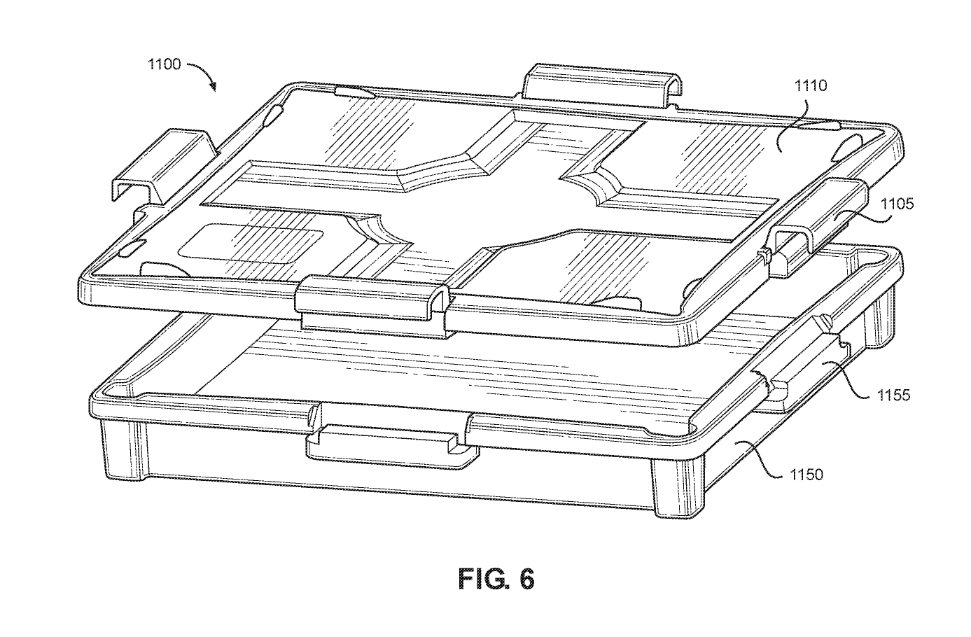

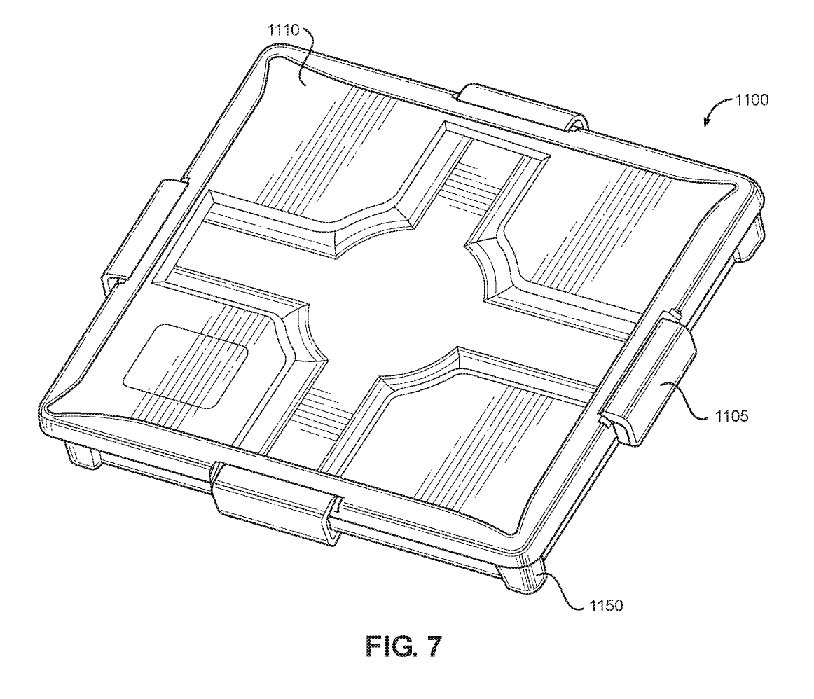

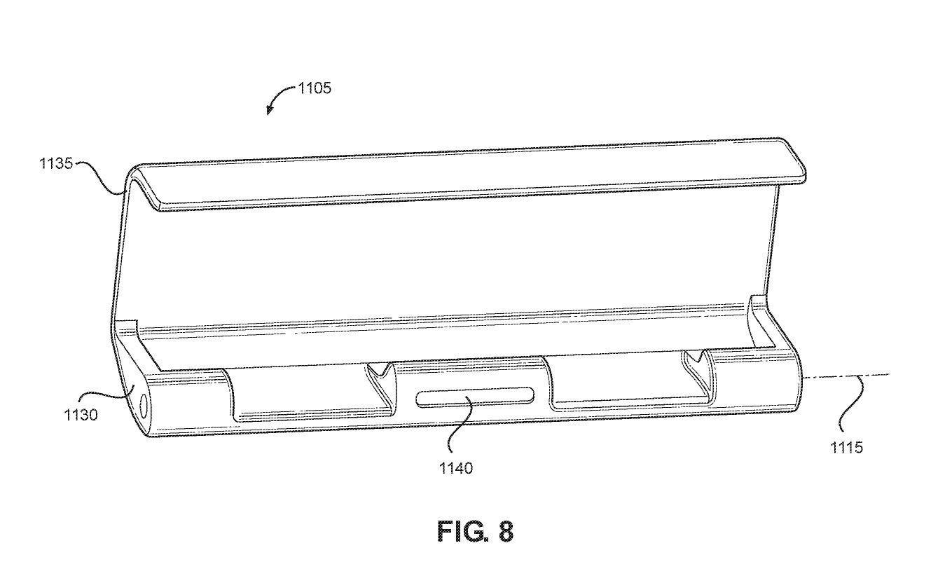

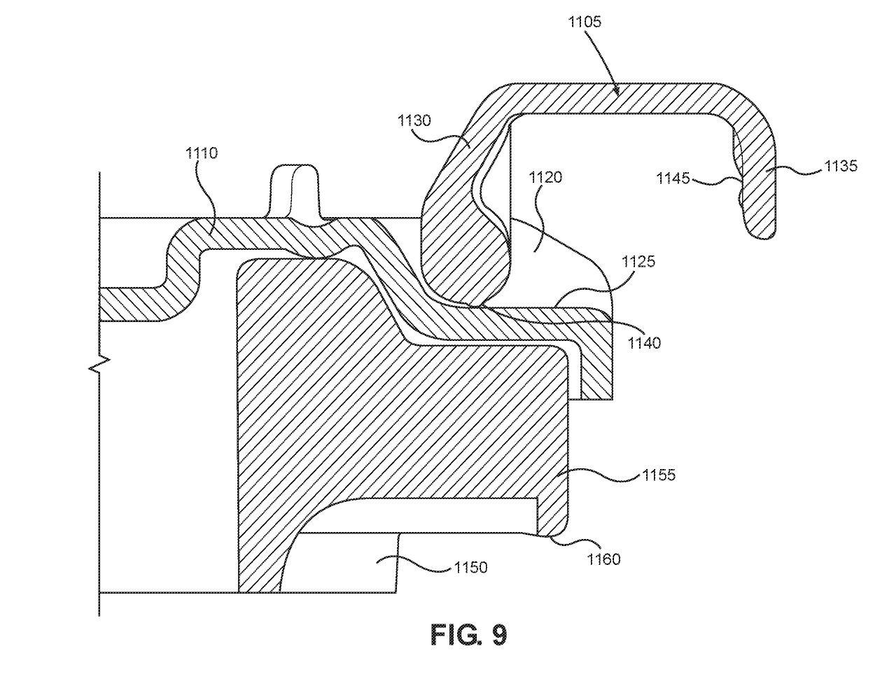

Referring to FIGS. 6-10, a substrate container 1100 is depicted in accordance with an embodiment of the present invention. Substrate container 1100 includes many of the same components and attributes as substrate container 100, which should be apparent from the drawings. Substrate container 1100 includes a plurality of latches. Preferably, each of the latches is substantially identical. Accordingly, for simplicity, only a latch 1105 is discussed below. Latch 1105 is pivotally mounted to a cover 1110 to rotate about a hinge axis 1115. Latch 1105 is mounted within a latch recess 1120 defined in cover 1110, as shown in FIG. 9. Latch recess 1120 includes a flat portion 1125 that is substantially parallel to hinge axis 1115. Latch 1105 includes a hinge portion 1130 and a hook portion 1135. In some embodiments, hinge portion 1130 includes a detent 1140 that projects radially outward from hinge axis 1115. Detent 1140 is dimensioned to interfere with flat portion 1125 when latch 1105 is in an open or unlatched position (FIG. 14). This interference is enough to cause friction between hinge portion 1130 and flat portion 1125 when latch 1105 is rotated into the unlatched position but not so much as to prevent latch 1105 from being rotated into the unlatched position. In some embodiments, a groove or notch 1145 is defined near a distal end of hook portion 1135.

A receptacle 1150 of substrate container 1100 includes latch handles that project radially outward from receptacle 1150. The latch handles are configured to align below the latches when cover 1110 is in place on receptacle 1150. For simplicity, only a latch handle 1155 is discussed below. In some embodiments, latch handle 1155 includes a handle detent 1160. Handle detent 1160 and groove notch 1145 cooperate to provide a snapping engagement between latch 1105 and latch handle 1155.

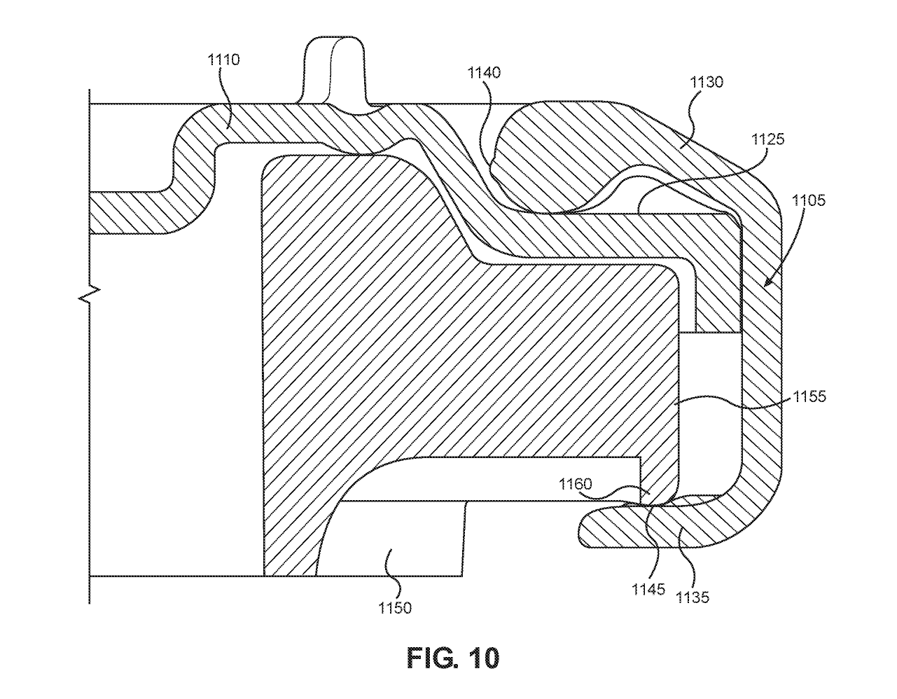

In operation, latch 1105 can be rotated into an unlatched position (FIG. 9). The friction caused by the interference between hinge portion 1130 of latch 1105 and flat portion 1125 of latch recess 1120 enables latch 1105 to maintain the unlatched position. Cover 1110 is placed onto receptacle 1150 with latch 1105 aligned over latch handle 1155. Cover 1110 is pressed downward onto receptacle 1150, and latch 1105 is rotated into a latched position (FIG. 10). In the latched position, groove 1145 of hook portion 1135 engages handle detent 1160 to secure latch 1105 (and cover 1110) to latch handle 1155 (and receptacle 1150).

Functionally, the friction between detent 1140 and flat portion 1125 in the latching arrangement of FIGS. 6-10 enables latch 1105 to be held in the open or unlatched position while cover 1110 is placed onto receptacle 1150 for easier assembly. Also, latch 1105 is engaged to latch handle 1155 by a downward motion coincidental with the downward pressure applied to cover 1110 to secure thin substrates inside substrate container 1100. That is, the latching action is not counter to the seating action of cover 1110 but is instead complementary to the seating action.

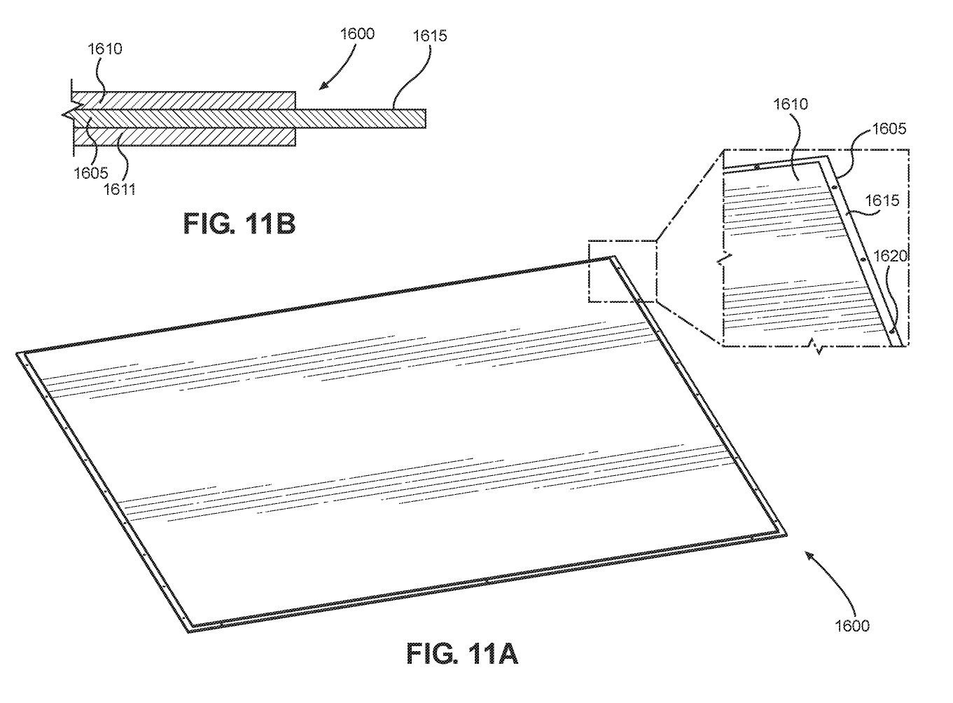

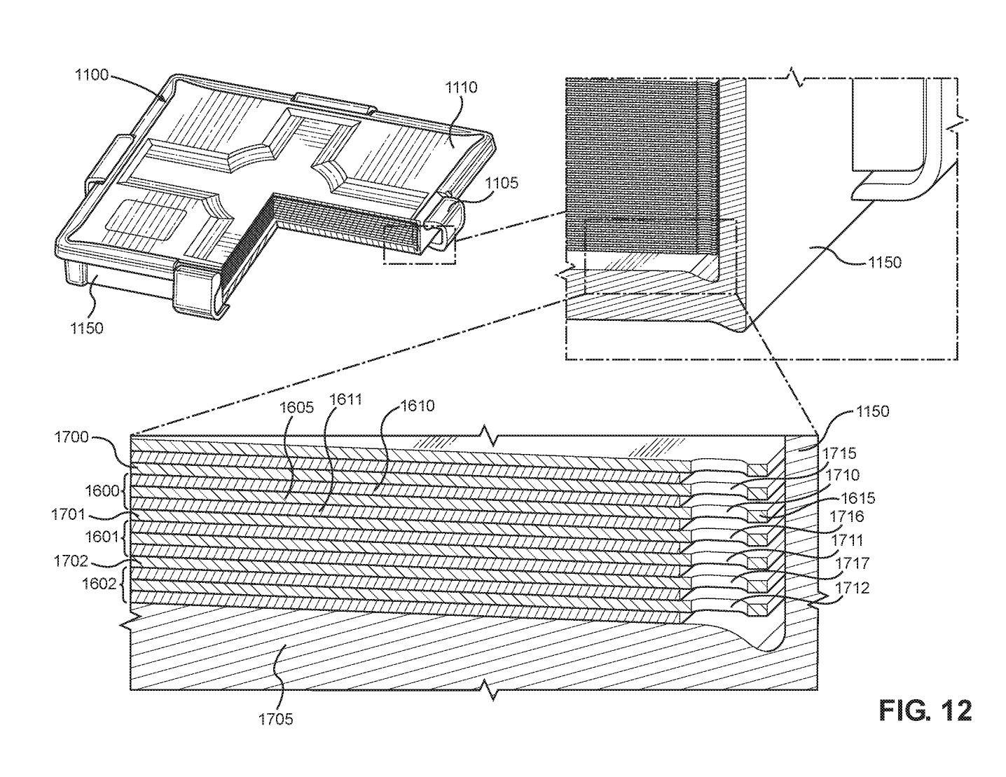

Referring to FIGS. 11A, 11B, and 12, a protective insert 1600 is depicted in accordance with an embodiment of the present invention. One aspect of a protective insert 1600 is shown in isolation in FIGS. 11A and 11B, and in assembly in substrate container 1100 in FIG. 12. Protective insert 1600 includes a rigid core possibly a polymer material 1605 clad on both sides by protective layers 1610 and 1611. An exposed edge portion 1615 of polymer core 1605 extends laterally from protective layers 1610 and 1611. In some embodiments, apertures (one of which is labeled 1620) are defined in exposed edge portion 1615, the apertures passing through a thickness of exposed edge portion 1615. In some embodiments, core 1605 and protective layers 1610 and 1611 are constructed from materials that are electrostatic dissipative (ESD). In some embodiments, core 1605 is less than 1 mm thick. Those of ordinary skill in the art recognize that a protective insert may be designed with various materials based on a specific flexible substrate that requires protection during storage and shipping. For example, a protective layer may include a foam insert without a rigid core.

In assembly, protective inserts are disposed interstitially between substrates within substrate container 1100 to form a composite stack of protective inserts and substrates (FIG. 12). Specifically, FIG. 12 shows protective inserts 1600-1602 being used with flexible substrates 1700-1702. In the depicted embodiment, a lowermost of the protective inserts (i.e., protective insert 1602) is installed at the bottom of the composite stack to seat against the interior surface of a base portion 1705 of receptacle 1150 (or, when utilized, against the top surface of spacer 1000). Likewise, a protective insert can be installed at the top of the composite stack. In some embodiments, at least some of the apertures formed in the exposed edge portions of the protective inserts are aligned with apertures formed in exclusion areas of the substrates. For example, in FIG. 12, apertures 1710-1712 formed in protective inserts 1600-1602 are aligned with apertures 1715-1717 formed in substrates 1700-1702.

Functionally, protective inserts 1600-1602 provide support across the span of substrates 1700-1702 to avoid excessive flexing during shipping and handling. Protective inserts 1600-1602 also prevent collisions between substrates 1700-1702 within substrate container 1100. Polymer core 1605 provides durability to protective insert 1600 for handling of protective insert 1600 and resident substrates. Exposed edge 1615 and, where utilized, the apertures of protective insert 1600 are amenable to handling with automation.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respect, only illustrative. Changes may be made in details, particularly in matters of shape, size, and arrangement of parts without exceeding the scope of the disclosure. The disclosure's scope is, of course, defined in the language in which the appended claims are expressed.

What is claimed is:

1. A substrate container comprising:
a receptacle including:
a base portion configured to support a flexible substrate, and
a side wall portion extending upward from the base portion; and
a cover configured to define a closure over the receptacle,
wherein the substrate container includes at least one of:
A) a first alignment feature located on an exterior surface of the receptacle and configured to interface with automation for aligning the receptacle; and
B) a contoured surface located on the cover and configured to apply a compressive load to the contents of the substrate container.

2. The substrate container of claim 1, wherein the receptacle includes the first alignment feature, and wherein the receptacle further includes a second alignment feature located on the exterior surface of the receptacle, the second alignment feature being configured to interface with automation for aligning the receptacle.

3. The substrate container of claim 2, wherein the first alignment feature is a recessed oval or rectangular boss, and the second alignment feature is a recessed circular boss.

4. The substrate container of claim 3, wherein the recessed circular boss lies along a major axis of the oval boss.

5. The substrate container of claim 1, wherein the cover includes the contoured surface, and wherein the contoured surface extends downward relative to a remainder of the cover.

6. The substrate container of claim 5, wherein the contoured surface is in the shape of a cross.

7. The substrate container of claim 1, wherein the side wall portion includes planar sections and corners that bridge adjacent ones of the planar sections, the corners protruding radially outward to define relief areas.

8. The substrate container of claim 1, wherein the cover includes a stacking feature configured to retain a second substrate container stacked atop the substrate container.

9. The substrate container of claim 1, further comprising a spacer mounted in the receptacle, the spacer being configured to elevate a substrate relative to the base portion.

10. The substrate container of claim 9, wherein the spacer includes an RFID device programmed to convey information about the substrate.

11. The substrate container of claim 1, further comprising a protective insert, the protective insert including a core clad on a first side by a first protective layer and clad on a second side by a second protective layer, wherein the protective insert is configured to prevent collisions between substrates within the substrate container.

12. The substrate container of claim 11, wherein an exposed edge portion of the polymer core extends laterally from the first and second protective layer.

13. The substrate container of claim 12, wherein an aperture is defined in the exposed edge portion.

14. A method of storing a flexible substrate within a substrate container including a receptacle and a cover, the receptacle including a base portion and a side wall portion extending upward from the base portion, the method comprising:
placing the flexible substrate on the base portion;
closing the receptacle with the cover; and
at least one of:
aligning the receptacle by causing a first alignment feature to interface with automation, the first alignment feature being located on an exterior surface of the receptacle; and
applying a compressive load to the contents of the substrate container with a contoured surface of the cover.

15. The method of claim 14, wherein the method includes aligning the receptacle, the method further comprising aligning the receptacle by causing a second alignment feature to interface with automation, the second alignment feature being located on the exterior surface of the receptacle.

16. The method of claim 15, wherein the first alignment feature is an oval or rectangular recessed boss, and the second alignment feature is a recessed circular boss.

17. The method of claim 16, wherein the circular boss lies along a major axis of the oval boss.

18. The method of claim 14, wherein the method includes applying the compressive load, and the contoured surface extends downward relative to a remainder of the cover.
